(19) United States
(12) Patent Application Publication
(10) Pub. No.: US 2026/0123555 A1
(43) Pub. Date: Apr. 30, 2026

(54) POWER MODULE

(71) Applicants: HYUNDAI MOTOR COMPANY, Seoul (KR); KIA CORPORATION, Seoul (KR)

(72) Inventors: Han Jin Do, Hwaseong-si (KR); Dong Hwan Lee, Hwaseong-si (KR); Jin Myeong Yang, Hwaseong-si (KR); Sung Won Park, Hwaseong-si (KR)

(73) Assignees: HYUNDAI MOTOR COMPANY, Seoul (KR); KIA CORPORATION, Seoul (KR)

(21) Appl. No.: 19/205,407

(22) Filed: May 12, 2025

(30) Foreign Application Priority Data
Oct. 30, 2024 (KR) 10-2024-0150962

(51) Int. Cl. H01L 23/498; H01L 23/14; H01L 23/31

(52) U.S. Cl. CPC H10W 90/701; H10W 70/6875; H10W 74/111

(57) ABSTRACT

A power module is provided. The power module includes a substrate provided with a chip mounted thereon, a molded portion provided to surround the substrate and the chip, a lead portion having one end electrically connected to the chip inside the molded portion and the other end exposed to an outside of the molded portion, and an insulating rib portion protruding from an outer surface of the molded portion on which the lead portion is provided.

### CROSS-REFERENCE TO RELATED APPLICATION(S)

This application claims benefit of priority to Korean Patent Application No. 10-2024-0150962 filed on Oct. 30, 2024, in the Korean Intellectual Property Office, the disclosure of which is incorporated herein by reference in its entirety.

### TECHNICAL FIELD

The present disclosure relates to a power module.

### BACKGROUND

As interest in the environment has increased, eco-friendly vehicles equipped with electric motors as a power source are on the rise. Eco-friendly vehicles are also called electrified vehicles, and representative examples include electric vehicles (EVs) and hybrid electric vehicles (HEVs). An inverter is used as a core component for power control that affects the performance and efficiency of the eco-friendly vehicles.

An inverter is a device converting direct current (DC) power into alternating current (AC) power and may drive an electric motor by receiving power from a high-voltage battery. The inverter includes a power module as a core component. The power module processes high voltage and current to perform power conversion.

In the design of a power module, securing the creepage distance between the signal lead and the power lead is useful in terms of maintaining signal accuracy and reliability.

In the related art, to secure the creepage distance between the signal lead and the power lead, a method of adjusting the position of the chip mounted on the substrate may be used; however, it may be useful to have a power module structure that may implement miniaturization of the power module while securing the creepage distance between the signal lead and the power lead.

### SUMMARY

An aspect of the present disclosure is to provide a power module suitable for miniaturization while providing sufficient creepage distance between signal leads and power leads.

According to an aspect of the present disclosure, a power module includes a substrate provided with a chip mounted thereon, a molded portion provided to surround the substrate and the chip, a lead portion having one (e.g., a first) end electrically connected to the chip inside the molded portion and the other (e.g., a second) end exposed to an outside of the molded portion, and an insulating rib portion protruding from an outer surface of the molded portion on which the lead portion is provided.

The lead portion may include a signal lead for transmitting a control signal and a power lead for transmitting power, and the insulating rib portion may include a signal lead insulation rib protruding from one surface on which the signal lead is provided and a power lead insulation rib protruding from one surface on which the power lead is provided.

The signal lead may include a plurality of signal pins disposed adjacently, and the signal lead insulation rib may be disposed between the plurality of signal pins.

An interval between the signal pins may be provided as first intervals and second intervals wider than the first intervals, and the signal lead insulation rib may include a first signal lead insulation rib disposed between the first intervals and a second signal lead insulation rib disposed between the second intervals.

A protruding length of the second signal lead insulation rib protruding from the outer surface of the molded portion may be provided to be longer than a protruding length of the first signal lead insulation rib protruding from the outer surface of the molded portion.

The signal lead insulation rib may be provided to surround an inner end of at least one of the signal pins, contacting the molded portion.

The signal lead insulation rib may be provided to surround inner ends of the plurality of signal pins disposed adjacently at the first interval.

The signal lead insulation rib may be provided to surround an inner end of an outermost signal pin among the plurality of signal pins disposed adjacently at the first interval.

The power lead may include a plurality of input terminals for supplying power to the chip and a plurality of output terminals for outputting power converted by the chip.

The power lead insulation rib may include a first power lead insulation rib provided in the input terminal disposed adjacently or in the output terminal disposed adjacently, and a second power lead insulation rib provided between the input terminals and the output terminals disposed adjacently.

A protruding length of the second power lead insulation rib protruding from the outer surface of the molded portion may be configured to be longer than a protruding length of the first power lead insulation rib protruding from the outer surface of the molded portion.

The power lead insulation rib may be provided to surround an inner end of at least one of the input terminals or the output terminals, contacting the molded portion.

According to an aspect of the present disclosure, a power module includes a substrate provided with a chip mounted thereon, a molded portion provided to surround the substrate and the chip, and a lead portion having one end electrically connected to the chip, inside of the molded portion, and the other end exposed to an outside of the molded portion. The lead portion is exposed to the outside through an insulating groove formed by being introduced inwardly from an outer surface of the molded portion.

The lead portion may include a signal lead for transmitting a control signal and a power lead for transmitting power, and the insulating groove may include a signal lead insulating groove exposing the signal lead externally and a power lead insulating groove exposing the power lead externally.

The signal lead may include a plurality of signal pins disposed adjacently, and at least one of the plurality of signal pins may be disposed inside the insulating groove.

The power lead may include a plurality of input terminals supplying power to the chip and a plurality of output terminals outputting power converted by the chip, and at least one of the plurality of input terminals and the plurality of output terminals may be disposed inside the insulating groove.

The lead portion may include a plurality of leads, and the insulating rib portion may include a plurality of insulating ribs. The plurality of insulating ribs may protrude between the plurality of leads.

### BRIEF DESCRIPTION OF DRAWINGS

The above and other aspects and features of the present disclosure will be understood from the following detailed description, taken in conjunction with the accompanying drawings.

FIG. 1 is a front perspective view of a power module according to an embodiment.

FIG. 2 is a rear perspective view of a power module according to an embodiment.

FIG. 3 is a plan view of a power module according to an embodiment.

FIG. 4 is a cross-sectional view taken along line I-I′ of FIG. 1.

FIG. 5A is a perspective view of a signal lead portion of a power module according to an embodiment, and FIG. 5B is a front view of a power module according to an embodiment.

FIG. 6A is a perspective view of a signal lead portion of a power module according to another embodiment, and FIG. 6B is a front view of a power module according to another embodiment.

FIG. 7A is a perspective view of a signal lead portion of a power module according to another embodiment, and FIG. 7B is a front view of a power module according to another embodiment.

FIG. 8A is a perspective view of a signal lead portion of a power module according to another embodiment, and FIG. 8B is a front view of a power module according to another embodiment.

FIG. 9A is a perspective view of a signal lead portion of a power module according to another embodiment, and FIG. 9B is a front view of a power module according to another embodiment.

FIG. 10A is a perspective view of a power lead portion of a power module according to an embodiment, and FIG. 10B is a rear view of a power module according to an embodiment.

FIG. 11A is a perspective view of a power lead portion of a power module according to another embodiment, and FIG. 11B is a rear view of a power module according to another embodiment.

FIG. 12A is a perspective view of a power lead portion of a power module according to another embodiment, and FIG. 12B is a rear view of a power module according to another embodiment.

FIG. 13A is a front perspective view of a power module according to another embodiment, and FIG. 13B is a front view of a power module according to another embodiment.

FIG. 14A is a rear perspective view of a power module according to another embodiment, and FIG. 14B is a rear perspective view of a power module according to another embodiment.

FIG. 15A is a front perspective view of a power module according to another embodiment, and FIG. 15B is a front view of a power module according to another embodiment. and

FIG. 16A is a rear perspective view of a power module according to another embodiment, and FIG. 16B is a rear perspective view of a power module according to another embodiment.

### DETAILED DESCRIPTION

The present disclosure may have various modifications and various embodiments, and specific embodiments are illustrated in the drawings and described in detail. However, this is not intended to limit the present disclosure to specific embodiments, and it should be understood that modifications, equivalents, and substitutes included in the spirit and technical scope of the present disclosure are included.

The terms first, second, and the like may be used to describe various components, but the components should not be limited by the terms. The terms are used for the purpose of distinguishing one component from another. For example, without departing from the scope of the present disclosure, the first component may be referred to as the second component, and similarly, the second component may also be referred to as the first component. The term “and/or” includes a combination of a plurality of related described items or one or more of a plurality of related described items.

The terms “unit,” “part,” “portion,” and the like may be used to describe various components, but the components should not be limited by the terms. The terms may refer to physically/visibly distinct configurations, and also to functions or configurations of corresponding parts even if the distinction/division is not (e.g., clearly) defined.

The terms used in this disclosure are used to describe example (e.g., specific) embodiments and are not intended to limit the present disclosure. The singular expression includes plural expressions unless the context (e.g., clearly) indicates otherwise. In this disclosure, the terms “include,” “have,” and the like should be understood to indicate the presence of features, numbers, steps, operations, components, parts, or combinations thereof described in the disclosure, but the terms do not preclude the possibility of the presence or addition of one or more other features, numbers, steps, operations, components, parts, or combinations thereof.

Unless otherwise provided, terms used herein, including technical or scientific terms, have the same meaning as generally understood by a person of ordinary skill in the art to which the present disclosure belongs. Terms that are in commonly used dictionaries should be interpreted as having a meaning consistent with the meaning they have in the context of the relevant technology, and are not interpreted in an ideal or overly formal sense unless provided in this disclosure.

In the disclosure herein, the terms “front,” “rear,” and the like used in relation to direction are provided based on the illustration in the drawing.

Herein, with reference to the attached drawings, an example embodiment will be described in more detail.

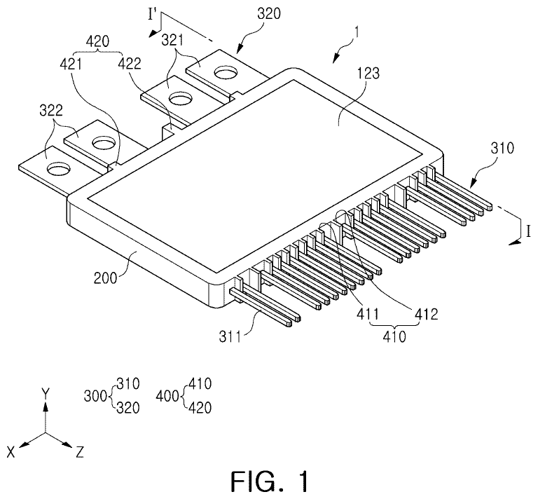

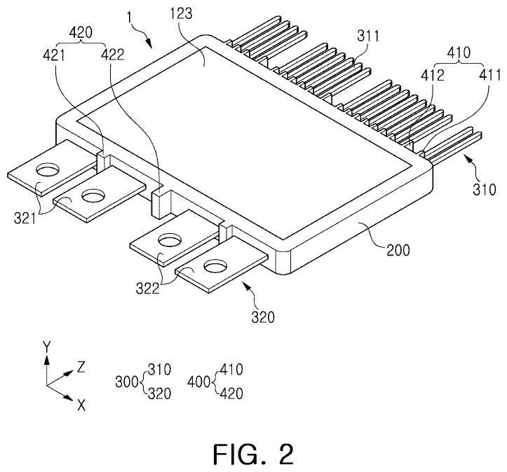

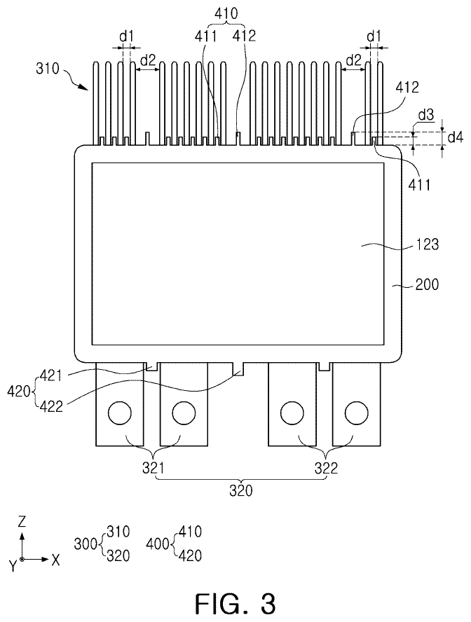

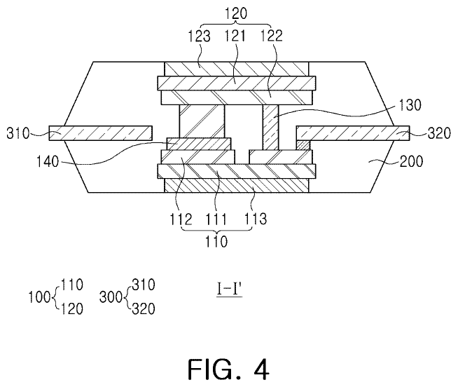

FIG. 1 is a front perspective view of a power module according to an embodiment, FIG. 2 is a rear perspective view of a power module according to an embodiment, FIG. 3 is a plan view of a power module according to an embodiment, and FIG. 4 is a cross-sectional view taken along line I-I′ of FIG. 1.

Referring to FIGS. 1 to 4, a power module 1 according to an embodiment includes a substrate 100, a molded portion 200, a lead portion 300, and an insulating rib portion 400. Meanwhile, the technical features of the power module 10 according to an embodiment are in the lead portion 300 exposed to the outside of the molded portion 200 and the insulating rib portion 400 for securing a creepage distance of the lead portion 300, and it is to be noted that various configurations commonly used in the power module technical field to which the present disclosure belongs may be applied to the configuration of other components/elements provided inside the molded portion 200. Hereinafter, for convenience of explanation, the internal configuration of a power module according to an embodiment is described as a power module 1 of a double-sided cooling method.

The substrate 100 may include a lower substrate 110 and an upper substrate 120. The lower substrate 110 may include a first insulating layer 111, a first internal metal layer 112 provided on the upper surface of the first insulating layer 111, and a first external metal layer 113 provided on the lower surface of the first insulating layer 111. The upper substrate 120 may include a second insulating layer 121, a second internal metal layer 122 provided on the lower surface of the second insulating layer 121, and a second external metal layer 123 provided on the upper surface of the second insulating substrate 122.

The upper substrate 120 may be disposed above the lower substrate 110. A spacer 130 may be provided between the upper substrate 120 and the lower substrate 110 for electrical/physical connection between the upper substrate 120 and the lower substrate 110. The spacer 130 may separate the upper substrate 120 and the lower substrate 110 from each other, and simultaneously, electrically connect the upper substrate 120 and the lower substrate 110 to each other.

A chip 140 may be disposed between the lower substrate 110 and the upper substrate 120. The chip 140 may be mounted on the upper portion of the lower substrate 110 or the lower portion of the upper substrate 120. The chip 140 may be electrically connected to at least one of the first internal metal layer 112 or the second internal metal layer 122.

The chip 140 may include at least one of, for example, an insulated gate bipolar transistor (IGBT), a compound semiconductor (SIC), a shunt circuit, a silicon controlled rectifier (SCR), a power transistor, a MOS transistor, a power rectifier, a power regulator, or a diode.

At least a portion of the first external metal layer 113 and the second external metal layer 123 may be exposed to the outside of the molded portion 200. A separate cooling channel (not illustrated) may be connected to a portion of the first external metal layer 113 and the second external metal layer 123 exposed to the outside of the molded portion 200. The first external metal layer 113 and the second external metal layer 123 may release heat generated during operation of the power module 1 to the outside.

The lead portion 300 may be provided to input/output current or input/output control signals. One end of the lead portion 300 may be electrically connected to the chip 140 inside the molded portion 200. The other end of the lead portion 300 may be exposed to the outside of the molded portion 200.

One end of the lead portion 300 may be electrically connected to the chip 140 via at least one of the first internal metal layer 112 or the second internal metal layer 122 of the substrate 100, or may be directly connected to the chip 140.

The lead portion 300 may include a plurality of leads, and the leads may include a signal lead 310 for transmitting a control signal and a power lead 320 for transmitting power.

The signal lead 310 may be provided to input a control signal to the chip 140 mounted on the substrate 100 or to receive status information of the chip 140. The signal lead 310 may include a plurality of signal pins 311. One end of the signal pin 311 may be disposed inside the molded portion 200 and the other end may be exposed to the outside of the molded portion 200.

A plurality of the signal pins 311 may be disposed adjacent to each other in one direction on one surface of the molded portion 200. For example, the signal pins 311 may be disposed adjacent to each other in the X-axis direction based on FIG. 1. The plurality of signal pins 311 may be disposed at a first interval d1 or a second interval d2. In this case, the second interval d2 may be formed to be wider than the first interval d1. Among the plurality of signal pins 311, signal pins 311 having similar electrical specifications may be disposed at a first interval d1. In this case, similar electrical specifications may mean that the applied potentials are similar. Signal pins 311 having similar electrical specifications and signal pins 311 that are not similar may be disposed at a second interval d2 to be distinguished from each other. At least one insulating rib portion 400 may be provided between adjacent signal pins 311. The insulating rib portion 400 may be provided to secure an insulating distance between the signal pins 311. In detail, the insulating rib portion 400 may increase the creepage distance between the signal pins 311. In this case, the creepage distance between the signal pins 311 may refer to a shortest distance between the signal pins 311 measured along the surface of the molded portion 200. The insulating rib portion 400 may secure the creepage distance of the signal pin 311 to prevent electrical interference and noise generation between terminals.

The power lead 320 may be provided to supply power to the chip 140 mounted on the substrate 100 or to output power converted by the chip 140. The power lead 320 may include, for example, a plurality of input terminals 321 connected to a high-voltage battery (not illustrated) to receive direct current and supply the current to the chip 140 and a plurality of output terminals 322 to output alternating current converted by the chip 140.

One end of the input terminal 321 and one end of the output terminal 322 may be disposed inside the molded portion 200 and may be electrically connected to the substrate 100 or the chip 140. The other ends of the input terminal 321 and the output terminal 322 may be exposed to the outside of the molded portion 200. The input terminal 321 and the output terminal 322 may be disposed adjacent to each other in one direction. For example, the input terminal 321 and the output terminal 322 may be disposed in multiple numbers adjacent to each other in the X-axis direction on the other surface of the molded portion 200.

At least one insulating rib portion 400 may be provided between the input terminals 321 or between the output terminals 322. The insulating rib portion 400 may be provided in between the input terminals 321, between the output terminals 322, and/or between the input terminal 321 and the output terminal 322, to secure an insulating distance between the terminals. In detail, the insulating rib portion 400 may increase the creepage distance of the terminals constituting the power lead 320. In this case, the creepage distance may refer to the shortest distance between the terminals constituting the power lead 320, measured along the surface of the molded portion 200. The insulating rib portion 400 may secure the creepage distance between the terminals constituting the power lead 320 to prevent electrical interference and noise generation between the terminals.

The molded portion 200 may form the exterior of the power module 1. The molded portion 200 may be provided to surround the substrate 100 and the chip 140. The molded portion 200 may be provided with various engineering plastics. For example, the molded portion 200 may be provided using an epoxy molding compound (EMC).

The molded portion 200 may be provided in the inner space between the lower substrate 110 and the upper substrate 120 and provided to surround the outer peripheral surfaces of the lower substrate 110 and the upper substrate 120. At least a portion of the first outer metal layer 113 of the lower substrate 110 and at least a portion of the second outer metal layer 123 of the upper substrate 120 may be exposed to the outside of the molded portion 200. For example, at least a portion of the first outer metal layer 113 may be exposed to the lower surface of the molded portion 200, and at least a portion of the second outer metal layer 123 may be exposed to the upper surface of the molded portion 200.

One end of the lead portion 300 may be embedded in the inside of the molded portion 200. For example, the signal lead 310 and the power lead 320 may be electrically connected to the chip 140 or the substrate 100 while the signal lead 310 has one end and the power lead 320 has one end embedded in the inside of the molded portion 200. The other end of the signal lead 310 and the other end of the power lead 320 may be exposed to the outside of the molded portion 300. In this case, the signal lead 310 may be exposed to the outside on one side of the molded portion 200, and the power lead 320 may be exposed to the outside on the other side of the molded portion 200. However, the positions at which the signal lead 310 and the power lead 320 are exposed are not limited to the above-described embodiment, and may be exposed to the outside at various positions of the molded portion 200 depending on the design.

The insulating rib portion 400 may be provided on the outer surface of the molded portion 200. For example, the insulating rib portion 400 may be provided protruding from one surface of the molded portion 200 on which the lead portion 300 is provided. The insulating rib portion 400 may be formed (e.g., integrally) when the molded portion 200 is formed. Therefore, the insulating rib portion 400 and the molded portion 200 may be provided with the same material.

The insulating rib portion 400 may be provided to secure an insulating distance between the signal lead 310 and the power lead 320.

The insulating rib portion 400 may include a plurality of insulating ribs, and the insulating ribs may include a signal lead insulation rib 410 protruding from one surface of the molded portion 200 on which the signal lead 310 is provided, and a power lead insulation rib 420 protruding from one surface of the molded portion 200 on which the power lead 320 is provided.

The insulating rib portion 400 may be provided between the signal leads 310 and between the power leads 320 to increase the creepage distance. The creepage distance may refer to the surface distance on the insulator between conductors having different potentials. Therefore, the creepage distance between the signal pins 311 of the signal leads 310 may be increased by the signal lead insulation rib 410. In addition, the creepage distance between the input terminals 321 and between the output terminals 322 of the power lead 320, and between the input terminal 321 and the output terminal 322, may be increased by the power lead insulation rib 420. Herein, various embodiments of the insulating rib portion 400 will be described with reference to the drawings. In addition, the embodiments described below are the same or substantially the same to the configurations illustrated in FIGS. 1 to 4 except for the configuration of the insulating rib portion 400, and thus, the description of the same configuration is omitted and replaced with the description described above.

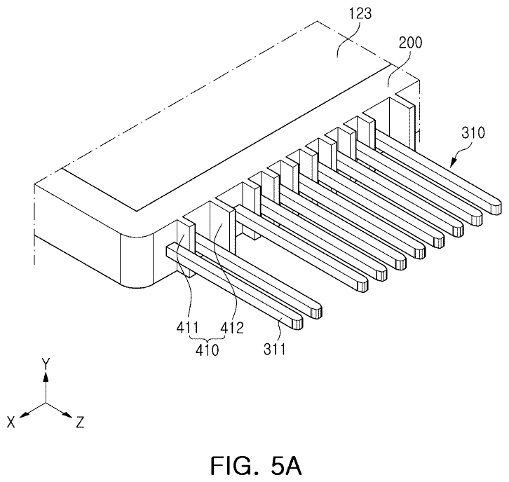

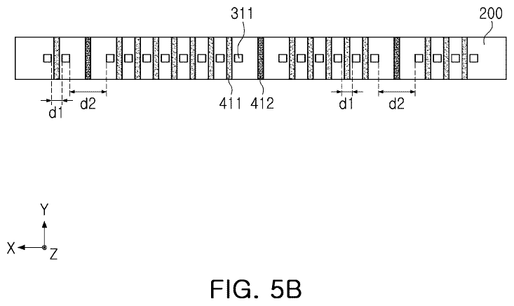

Referring to FIGS. 5A and 5B, a plurality of signal pins 311 may be provided on one surface of the molded portion 200. The plurality of signal pins 311 may be disposed adjacently in one direction. The plurality of signal pins 311 may be disposed at a first interval d1 and a second interval d2 wider than the first interval d1. Among the plurality of signal pins 311, the signal pins 311 having similar electrical specifications may be disposed at a first interval d1. Accordingly, signal pins 311 that are not similar may be disposed at a second interval d2 to be distinguished from signal pins 311 disposed at the first interval d1.

A signal lead insulation rib 410 may be provided to increase the creepage distance between signal pins 311. The signal lead insulation rib 410 may be provided between adjacent signal pins 311. For example, the signal lead insulation rib 410 may be provided in a protruding wall shape.

The signal lead insulation rib 410 may include a first signal lead insulation rib 411 disposed between the first interval d1 and a second signal lead insulation rib 412 disposed between the second interval d2. A protruding length d4 (see FIG. 3) of the second signal lead insulation rib 412 protruding from the outer surface of the molded portion 200 may be provided to be longer than a protruding length d3 (see FIG. 3) of the first signal lead insulation rib 411 protruding from the outer surface of the molded portion 200. Since the signal pins 311 disposed at the second interval d2 have different electrical specifications, a relatively large creepage distance may (e.g., needs to) be secured. Therefore, by ensuring the protruding length of the second signal lead insulation rib 412 provided between the second interval d2 to be relatively long, the creepage distance between the signal pins 311 disposed at the second interval d2 may be secured.

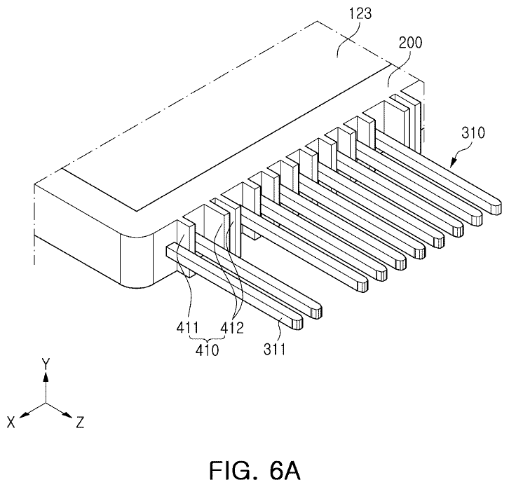

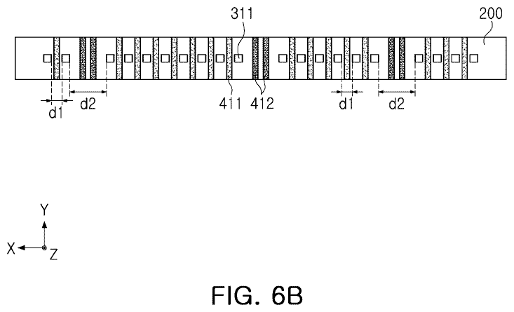

Meanwhile, referring to FIGS. 6A and 6B, to (e.g., more effectively) secure the creepage distance between signal pins 311 having different electrical specifications, a plurality of second signal lead insulation ribs 412 may be provided between the signal pins 311 disposed at the second interval d2. The shapes and the numbers of the first signal lead insulation ribs 411 and the second signal lead insulation ribs 412 may be changed according to the insulation specifications (e.g., requirements).

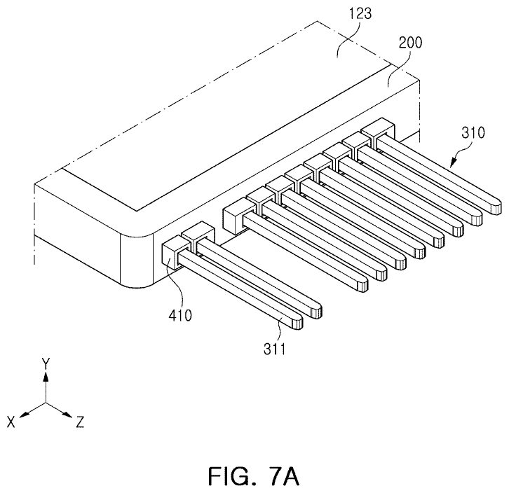

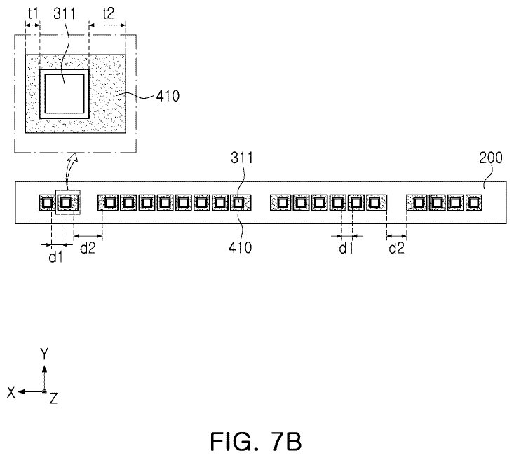

Referring to FIGS. 7A and 7B, the signal lead insulation rib 410 may be provided to surround the inner end of at least one signal pin 311, which comes into contact with the molded portion 200. At this time, the inner surface of the signal lead insulation rib 410 may be provided to be spaced apart from the outer surface of the signal pin 311. The signal lead insulation rib 410 may be provided in the shape of a quadrangular pillar, for example. In this case, a thickness t2 of some signal lead insulation ribs 410 disposed in the second interval d2, among the signal lead insulation ribs 410, may be provided to be thicker than a thickness t1 of some signal lead insulation ribs 410 disposed in the first intervals d1.

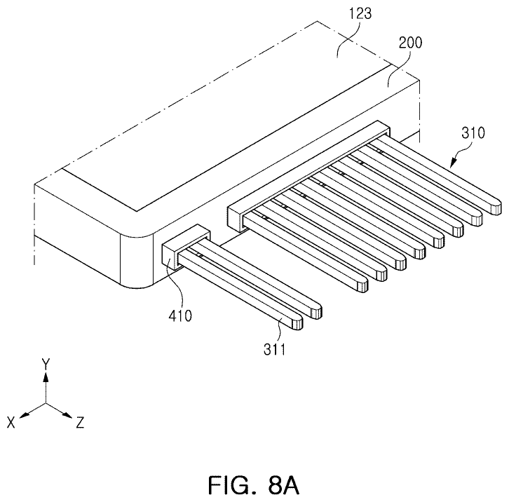

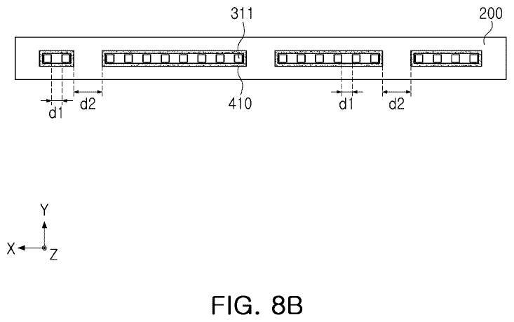

Referring to FIGS. 8A and 8B, the signal lead insulation rib 410 may be provided to surround inner ends of a plurality of signal pins 311, coming into contact with the molded portion 200. For example, the signal lead insulation rib 410 may be provided to surround the inner end of a plurality of signal pins 311 that are disposed adjacently at a first interval d1. Accordingly, signal pins 311 having similar electrical specifications may be disposed inside (e.g., at least) one signal lead insulation rib 410.

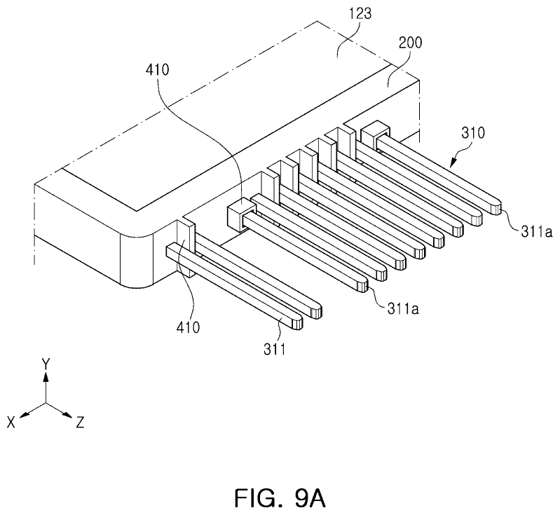

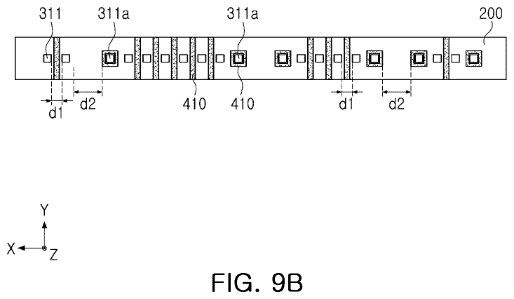

Referring to FIGS. 9A and 9B, the signal lead insulation rib 410 may be provided to surround the inner end of the signal pin 311a that is disposed at the outermost side among the plurality of signal pins 311 that are disposed adjacently at a first interval d1. The signal lead insulation rib 410 may be provided in a quadrangular pillar shape, for example. Accordingly, at least a portion of the signal lead insulation rib 410 may be disposed between the second interval d2 and at least a portion thereof may be disposed between the first interval d1. Meanwhile, a wall-shaped signal lead insulation rib 410 may be additionally provided between the first intervals d1. At this time, the protruding length of the quadrangular pillar-shaped signal lead insulation rib 410 may be provided to be equal to or longer than the protruding length of the wall-shaped signal lead insulation rib 410.

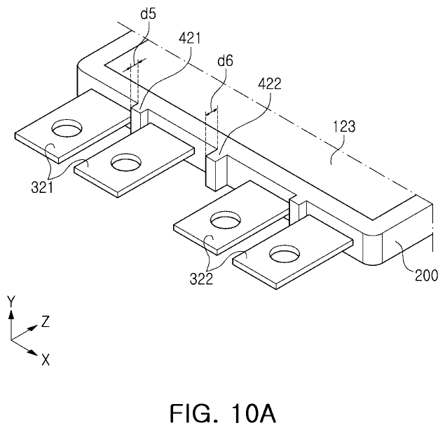

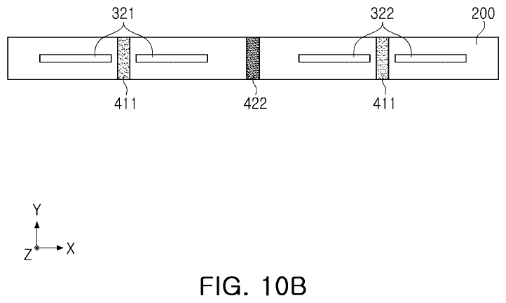

Referring to FIGS. 10A and 10B, a power lead 320 may be provided on one side of the molded portion 200. The power lead 320 may include a plurality of input terminals 321 and a plurality of output terminals 322. The power lead insulation rib 420 may be provided to protrude from one side of the molded portion 200 on which the power lead 320 is provided. The power lead insulation rib 420 may be provided to increase the creepage distance between the input terminals 321, between the output terminals 322, or between the input terminal 321 and the output terminal 322. To this end, the power lead insulation rib 420 may be provided (a) between the input terminals 321, (b) between the output terminals 322, and/or (c) between the input terminal 321 and the output terminal 322. The power lead insulation rib 420 may be provided in a protruding wall shape, for example.

The power lead insulation rib 420 may include a first power lead insulation rib 421 provided between adjacently disposed input terminals 321 or between adjacently disposed output terminals 322, and a second power lead insulation rib 422 provided between adjacently disposed input terminals 321 and output terminals 322. At this time, a protruding length d6 of the second power lead insulation rib 422 protruding from the outer surface of the molded portion 200 may be provided longer than a protruding length d5 of the first power lead insulation rib 421 protruding from the outer surface of the molded portion 200. Since the difference in electrical specifications between the input terminal 321 and the output terminal 322 is relatively large, the protruding length d6 of the second power lead insulation rib 422 may be provided longer than the protruding length d5 of the first power lead insulation rib 421 to (e.g., effectively) secure the creepage distance between the input terminal 321 and the output terminal 322.

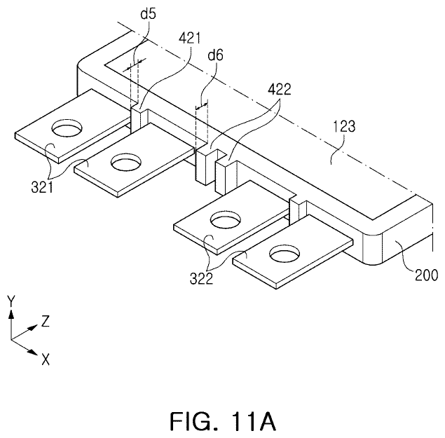

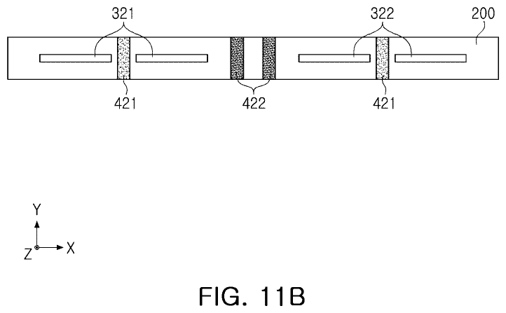

Meanwhile, referring to FIGS. 11A and 11B, to (e.g., more effectively) secure the creepage distance between the input terminal 321 and the output terminal 322, a plurality of second power lead insulation ribs 422 may be provided between the input terminal 321 and the output terminal 322. The shapes and numbers of the first power lead insulation ribs 421 and the second power lead insulation ribs 422 may be changed according to insulation specifications (e.g., requirements).

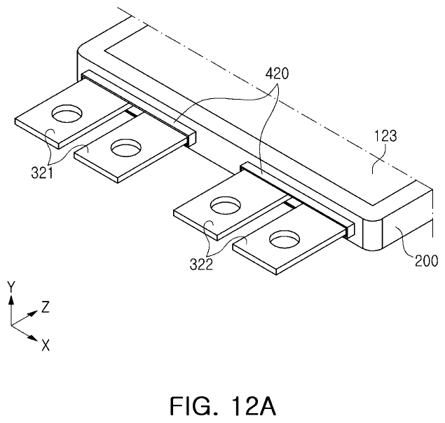

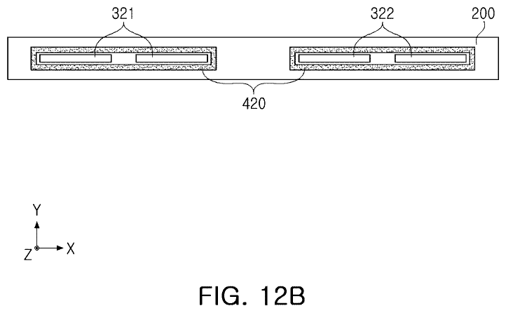

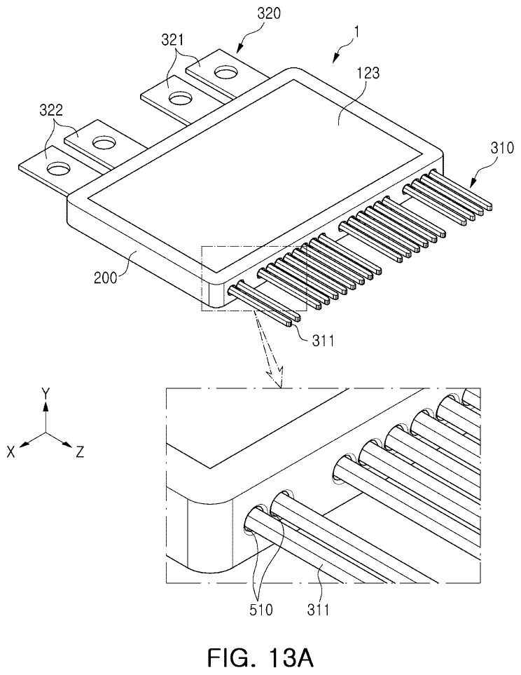

Referring to FIGS. 12A and 12B, the power lead insulation rib 420 may be provided to surround an inner end of at least one of the input terminals 321 or the output terminals 322, coming into contact with the molded portion 200. For example, the power lead insulation rib 420 may be provided to surround inner ends of a plurality of adjacently disposed input terminals 321 or a plurality of adjacently disposed output terminals 322, coming into contact with the molded portion 200. As another example, the power lead insulation rib 420 may be provided to surround respective inner ends of the plurality of input terminals 321 and the plurality of output terminals 322, coming into contact with the molded portion 200.

At this time, the power lead insulation rib 420 may be provided in a quadrangular pillar shape. The inner surface of the power lead insulation rib 420 and the outer surface of the input terminal 321 or the output terminal 322 may be provided to be spaced apart from each other. Input terminals 321 or output terminals 322 having similar electrical specifications may be disposed on the inner surface of any one of the power lead insulation ribs 420.

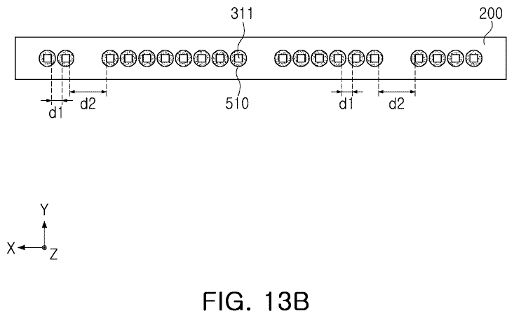

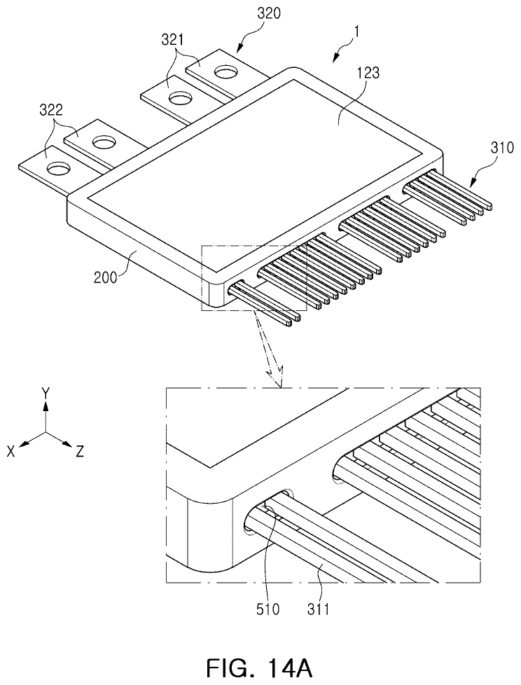

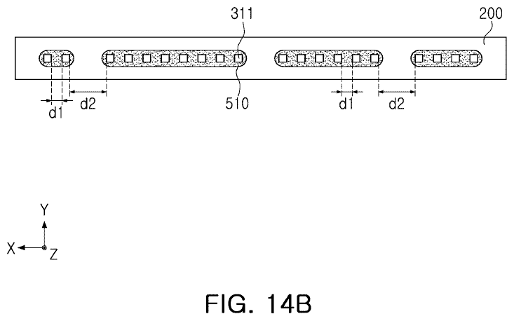

FIG. 13A is a front perspective view of a power module according to another embodiment, FIG. 13B is a front view of a power module according to another embodiment, FIG. 14A is a rear perspective view of a power module according to another embodiment, and FIG. 14B is a rear view of a power module according to another embodiment.

Referring to FIGS. 13A to 14B, a power module 1 according to another embodiment may include a substrate 100 on which a chip is mounted, a molded portion 200 provided to surround the substrate 100 and the chip, and a lead portion 300 whose one end is electrically connected to the chip inside the molded portion 200 and whose other end is exposed to the outside of the molded portion 200.

The lead portion 300 may include a signal lead 310 for transmitting a control signal and a power lead 320 for transmitting power. The signal lead 310 may include a plurality of signal pins 311 disposed adjacently. The power lead 320 may include a plurality of input terminals 321 for supplying power to the chip and a plurality of output terminals 322 for outputting power converted by the chip.

The molded portion 200 may be provided with an insulating groove 500. The insulating groove 500 may be formed by a portion of the outer surface of the molded portion 200 being drawn inward. The insulating groove 500 may be provided on one surface of the molded portion 200 in which the lead portion 300 is provided. The lead portion 300 may be exposed to the outside through the insulating groove 500 of the molded portion 200. In detail, at least a portion of the lead portion 300 may be disposed inside the insulating groove 500.

The insulating groove 500 may include a signal lead insulating groove 510 that exposes the signal lead 310 to the outside and a power lead insulating groove 520 that exposes the power lead 320 to the outside.

The signal lead insulating groove 510 may be formed by one surface of the molded portion 200 that is in contact with the inner end of the signal pin 311, being drawn inward. The signal lead insulating groove 510 may increase the creepage distance between adjacently disposed signal pins 311.

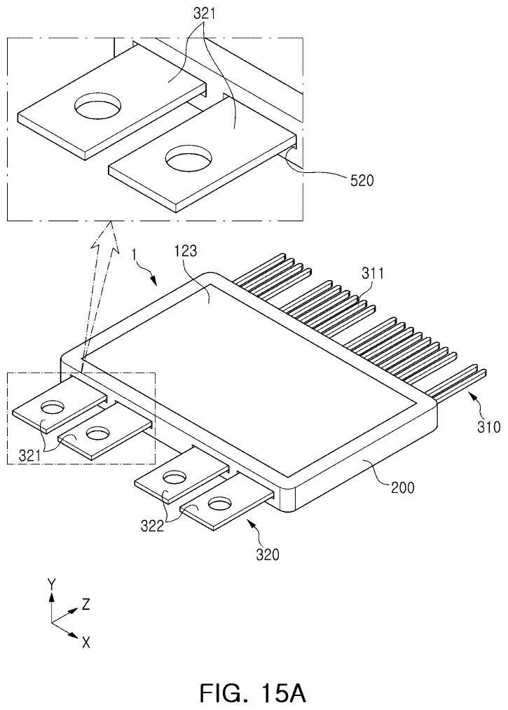

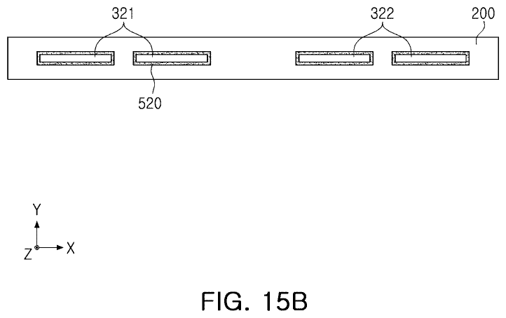

At least one signal pin 311 may be disposed inside the signal lead insulating groove 510. For example, the signal lead insulating groove 510 is provided corresponding to the number of signal pins 311, so that one signal pin 311 may be disposed in one signal lead insulating groove 510 (see FIGS. 13A and 13B). In addition, a plurality of signal pins 311 having the same electrical specifications may be disposed inside the signal lead insulating groove 510 (see FIGS. 15A and 15B).

The power lead insulating groove 520 may be formed by inwardly introducing one surface of the molded portion 200 that comes into contact with the inner end of the input terminal 321 or the output terminal 322. The power lead insulating groove 520 may increase the creepage distance between adjacently disposed input terminals 321 or output terminals 322.

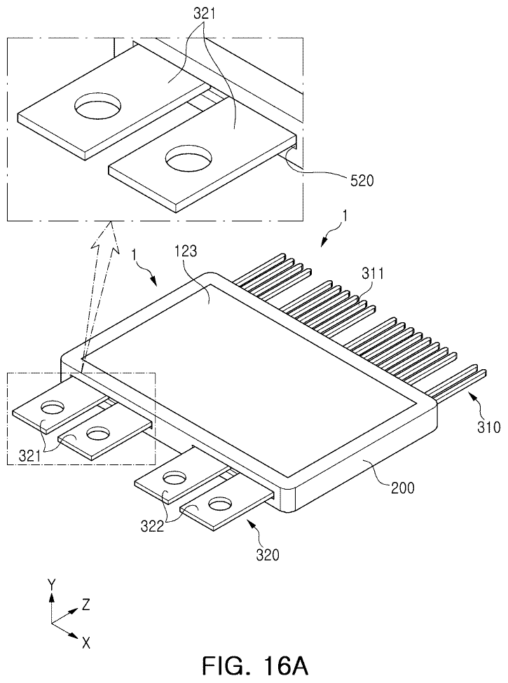

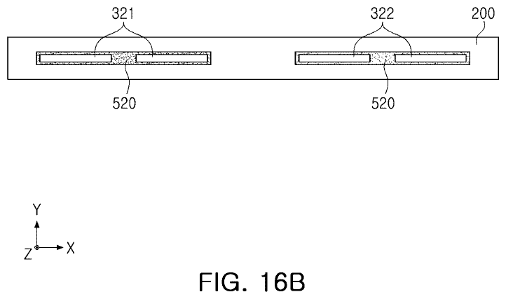

At least one of a plurality of input terminals 321 and output terminals 322 may be disposed inside the power lead insulating groove 520. For example, a single input terminal 321 or output terminal 322 may be disposed inside the power lead insulating groove 520 (see FIGS. 14A and 14B), or a plurality of input terminals 321 or output terminals 322 having the same/similar electrical specifications may be disposed (see FIGS. 16A and 16B).

In the power module 1 according to the embodiments described above, the insulating rib portion 400 and the insulating groove 500 may increase the creepage distance of the signal pin 311 or the input/output terminal 321, 322 constituting the signal lead 310 or the power lead 320. Therefore, even if the spatial distance of the signal pin 311 or the input/output terminal 321, 322 is disposed close, the insulation performance may be secured, so there is an effect in miniaturizing the power module 1.

In addition, the embodiments described above may be implemented in combination with each other as long as they do not correspond to contradictory configurations. For example, the configurations of the insulating rib portion 400 and the insulating groove 500 in the power module 1 according to embodiments may be applied (e.g., substantially) simultaneously.

As set forth above, a power module according to an embodiment has an effect of miniaturization while securing a sufficient creepage distance between a signal lead and a power lead.

While example embodiments have been illustrated and described above, it will be apparent to those skilled in the art that modifications and variations could be made without departing from the scope of the present disclosure as provided by the appended claims.

What is claimed is:

1. A power module comprising:
a substrate provided with a chip mounted thereon;
a molded portion provided to surround the substrate and the chip;
a lead portion having a first end electrically connected to the chip inside the molded portion and a second end exposed to an outside of the molded portion; and
an insulating rib portion protruding from an outer surface of the molded portion on which the lead portion is provided.

2. The power module of claim 1, wherein the lead portion includes a signal lead for transmitting a control signal and a power lead for transmitting power, and
the insulating rib portion includes a signal lead insulation rib protruding from a first surface on which the signal lead is provided and a power lead insulation rib protruding from a first surface on which the power lead is provided.

3. The power module of claim 2, wherein the signal lead includes a plurality of adjacent signal pins, and the signal lead insulation rib is disposed between the plurality of signal pins.

4. The power module of claim 3, wherein an interval between the signal pins is provided as a first interval and a second interval, wherein the second interval is wider than the first interval, and
the signal lead insulation rib includes a first signal lead insulation rib disposed in the first interval and a second signal lead insulation rib disposed in the second interval.

5. The power module of claim 4, wherein a protruding length of the second signal lead insulation rib protruding from the outer surface of the molded portion is provided to be longer than a protruding length of the first signal lead insulation rib protruding from the outer surface of the molded portion.

6. The power module of claim 4, wherein a plurality of the second signal lead insulation ribs are disposed between the second intervals.

7. The power module of claim 4, wherein the signal lead insulation rib is provided to surround an inner end of at least one of the signal pins, contacting the molded portion.

8. The power module of claim 7, wherein the signal lead insulation rib is provided to surround an inner end of at least one of the plurality of signal pins adjacent to the first interval.

9. The power module of claim 7, wherein the signal lead insulation rib is provided to surround an inner end of an outermost signal pin of the plurality of signal pins adjacent to the first interval.

10. The power module of claim 2, wherein the power lead includes a plurality of input terminals for supplying power to the chip and a plurality of output terminals for outputting power converted by the chip.

11. The power module of claim 10, wherein the power lead insulation rib includes:
a first power lead insulation rib provided between adjacent input terminals or between adjacent output terminals; and
a second power lead insulation rib provided between input terminals and adjacent output terminals.

12. The power module of claim 11, wherein a protruding length of the second power lead insulation rib protruding from the outer surface of the molded portion is configured to be longer than a protruding length of the first power lead insulation rib protruding from the outer surface of the molded portion.

13. The power module of claim 10, wherein the power lead insulation rib is provided to surround an inner end of at least one of the input terminals or the output terminals, contacting the molded portion.

14. A power module comprising:
a substrate provided with a chip mounted thereon;
a molded portion provided to surround the substrate and the chip; and
a lead portion having a first end electrically connected to the chip, inside of the molded portion, and a second end exposed to an outside of the molded portion,
wherein the lead portion is exposed to the outside through an insulating groove formed by being introduced inwardly from an outer surface of the molded portion.

15. The power module of claim 14, wherein the lead portion includes a signal lead for transmitting a control signal and a power lead for transmitting power, and
the insulating groove includes a signal lead insulating groove exposing the signal lead externally and a power lead insulating groove exposing the power lead externally.

16. The power module of claim 15, wherein the signal lead includes a plurality of adjacent signal pins, and
at least one of the plurality of signal pins is disposed inside the signal lead insulating groove.

17. The power module of claim 15, wherein the power lead includes a plurality of input terminals supplying power to the chip and a plurality of output terminals outputting power converted by the chip.

18. The power module of claim 17, wherein the plurality of input terminals are disposed inside the power lead insulating groove.

19. The power module of claim 17, wherein the plurality of output terminals are disposed inside the power lead insulating groove.

20. The power module of claim 1, wherein the lead portion includes a plurality of leads, and
the insulating rib portion includes a plurality of insulating ribs,
wherein the plurality of insulating ribs protrude between the plurality of leads.
